(19) United States
(12) Patent Application Publication
(10) Pub. No.: US 2008/0246126 A1
(43) Pub. Date: Oct. 9, 2008

(54) STACKED AND SHIELDED DIE PACKAGES WITH INTERCONNECTS

(75) Inventors: Philip H. Bowles, Fountain Hills, AZ (US); Li Li, Scottsdale, AZ (US); Lianjun Liu, Chandler, AZ (US)

Correspondence Address: INGRASSIA FISHER & LORENZ, P.C. (FS), 7010 E. COCHISE ROAD, SCOTTSDALE, AZ, 85253, US

(73) Assignee: FREESCALE SEMICONDUCTOR, INC., Austin, TX (US)

(21) Appl. No.: 11/696,374

(22) Filed: Apr. 4, 2007

(51) Int. Cl. H01L 23/552; H01L 21/58

(52) U.S. Cl. 257/659; 438/109; 257/E23.114; 257/E21.505

(57) ABSTRACT

According to an example embodiment, a stacked die package 800 includes a first die (806), first active circuitry (808) disposed on an upper surface of the first die, and a first conductive pattern (820) disposed on the first active circuitry. The stacked die package further includes a second die (826) disposed over the first die, where the first die is wider than the second die in a cross-section of the stacked die package, second active circuitry (828) disposed on an upper surface of the second die, and a second conductive pattern (830) disposed on the second active circuitry. The stacked die package further includes a first wirebond (822) that connects the first conductive pattern to the second conductive pattern and a mold compound (824) disposed on the first die, the mold compound encapsulating the second die and the wirebond.

### TECHNICAL FIELD

This disclosure relates generally to stacked die packages, and more particularly to stacked die packages with interconnects.

### BACKGROUND

Vias are known structures that may be used to electrically connect a lower conductive structure such as a contact, pad, layer, or pattern to an upper conductive structure such as a contact, pad, layer, or pattern that is vertically separated from the lower conductive structure. Vias typically penetrate vertically through one or more horizontally arranged structural layers that separate the lower conductive structure and the upper conductive structure.

Stacked die packages are also known, and such packages are in mass production. Stacking die upon one another can provide significant area reduction. When there are Radio Frequency (RF) die circuits present, such as in a RF module formed as a stacked die package, it is desirable to shield the RF die circuits from each other.

Much industry effort has been focused in achieving the goal of shielding the RF die circuits by forming interconnects between the dies using vias that penetrate the die themselves. However, it is very challenging to fabricate vias through the die, make them conductive, and insulate them from the semiconductor without adding unacceptable cost or consuming too much semiconductor area. Example embodiments address these and other disadvantages of the conventional art.

### BRIEF DESCRIPTION OF THE DRAWINGS

Example embodiments will hereinafter be described in conjunction with the following drawing figures, wherein like numerals denote like elements, and wherein:

FIG. 1 is a sectional diagram illustrating various components of a stacked die package according to a first example embodiment;

FIG. 2 is a sectional diagram illustrating various components of a stacked die package according to a second example embodiment;

FIG. 3 is a sectional diagram illustrating various components of a stacked die package according to a third example embodiment;

FIG. 4 is a sectional diagram illustrating various components of a stacked die package according to a fourth example embodiment;

FIG. 5 is a sectional diagram illustrating various components of a stacked die package according to a fifth example embodiment;

FIG. 6 is a sectional diagram illustrating various components of a stacked die package according to a sixth example embodiment;

FIG. 7 is a sectional diagram illustrating various components of a stacked die package according to a seventh example embodiment;

FIG. 8 is a sectional diagram illustrating various components of a stacked die package according to an eighth example embodiment;

FIG. 9 is a sectional diagram illustrating various components of a stacked die package according to a ninth example embodiment;

FIG. 10 is a sectional diagram illustrating various components of a stacked die package according to a tenth example embodiment;

FIG. 11 is a sectional diagram illustrating various components of a stacked die package according to an eleventh example embodiment;

FIG. 12 is a sectional diagram illustrating various components of a stacked die package according to a twelfth example embodiment;

FIG. 13 is a sectional diagram illustrating various components of a stacked die package according to a thirteenth example embodiment; and

FIG. 14 is a sectional diagram illustrating various components of a stacked die package according to a fourteenth example embodiment.

### DETAILED DESCRIPTION OF EXAMPLE EMBODIMENTS

The following detailed description of example embodiments is not intended to limit the invention or the application and uses of the invention. Furthermore, there is no intention to be bound by any expressed or implied theory presented in the preceding technical field, background, or the following detailed description of example embodiments. Furthermore, other desirable features and characteristics of the invention will become apparent from the subsequent detailed description and the appended claims, taken in conjunction with the accompanying drawings and the foregoing technical field and background.

For simplicity and clarity of illustration, the drawing figures illustrate the general manner of construction, and descriptions and details of well-known features and techniques may be omitted to avoid unnecessarily obscuring inventive aspects. Additionally, elements in the drawings figures are not necessarily drawn to scale. For example, the dimensions of some of the elements or regions in some of the figures may be exaggerated relative to other elements or regions of the same or other figures to help improve understanding of the example embodiments.

The terms “first,” “second,” “third,” “fourth” and the like in the description and the claims, if any, may be used for distinguishing between similar elements and not necessarily for describing a particular sequential or chronological order. It is to be understood that the terms so used are interchangeable under appropriate circumstances such that the embodiments described herein are, for example, capable of use in sequences other than those illustrated or otherwise described herein. Furthermore, the terms “comprise,” “include,” “have” and any variations thereof, are intended to cover non-exclusive inclusions, such that a process, method, article, or apparatus that comprises, includes, or has a list of elements is not necessarily limited to those elements, but may include other elements not expressly listed or inherent to such process, method, article, or apparatus. The terms “left,” “right, ” “in,” “out,” “front,” “back,” “up,” “down,” “top,” “bottom,” “over,” “under,” “above,” “below” and the like in the description and the claims, if any, are used for describing relative positions and not necessarily for describing permanent positions in space. It is to be understood that the example embodiments described herein may be used, for example, in other orientations than those illustrated or otherwise described herein.

Example embodiments include methods of stacking, shielding, and interconnecting die without the use of vias through the semiconductors. Example embodiments further include stacked die packages that are shielded and interconnected without using vias through the semiconductors.

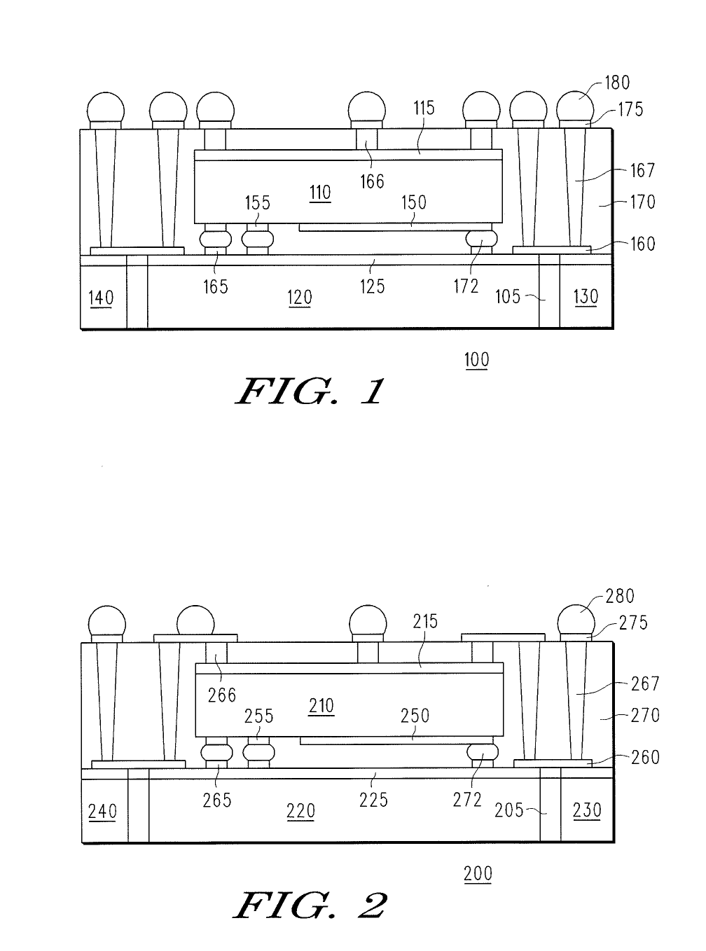

FIG. 1 is a sectional diagram illustrating various components of a stacked die package 100 according to a first example embodiment. As shown, the stacked die package 100 is shown attached to adjacent packages, prior to separation along the saw streets 105. The stacked die package 100 includes stacked die 110 and 120, each having die active circuitry 115 and 125, respectively.

A first conductive pattern, which includes bump pads 165, is disposed on the die 120. The stacked die package 100 further includes a plating bus 160. As illustrated, the plating bus 160 is disposed in the saw street 105. The saw streets 105 are areas that will be subsequently cut to separate the package 100 from adjacent packages. The placement of the plating bus 160 in the saw street 105 beneficially allows for the electroplating of high-aspect vias.

An RF shield 150, which shields RF die circuitry in the active circuitry 115 and 125 from each other, is disposed on a bottom surface of the die 110, as are bump pads 155. First conductive bumps 172 are disposed such that the RF shield 150 is spaced apart from the active circuitry 125. The RF shield 150 is grounded through at least one of the first conductive bumps 172 to the bottom die 120. The first conductive bumps 172 are disposed between bump pads 155 of the die 110 and bump pads 165 of the die 120, and between the bump pads 165 and the RF shield 150. In alternative embodiments, more than one die may be used in place of the single die 110 that is shown.

The stacked die package 100 further includes a mold compound 170. Vias 167 penetrate the mold compound 170 to contact the plating bus 160, and studs 166 penetrate the mold compound 170 to contact the active circuitry 115. A second conductive pattern 175 is disposed on the mold compound 170, the vias 167, and the studs 166. Second conductive bumps 180 are disposed on the second conductive pattern 175, and are used to attach the package 100 to another circuit. In alternative embodiments, the second conductive bumps 180 may be replaced by solder or some other means of attachment. In other embodiments, the second conductive bumps 180 or other means of attachment may not be present at all, as the circuit to which the package 100 is to be attached may include the conductive bumps, solder, or other means of attachment.

As illustrated in FIG. 1, the stacked die package 100 is shown at the wafer level. That is, the die 120 is shown as integral to the neighboring dies 130, 140, prior to being separated or singulated from the neighboring dies along the saw streets 105. According to some embodiments, after separation from the neighboring dies 130, 140, the stacked die package 100 may be used as a flip chip die.

According to some embodiments, the thickness of package 100 is about 350 to about 400 microns thick, including the second conductive bumps 180. Since vias are not made in the die 110, the width of the die 110 may be less than the width of the die 120.

Processes employed in the manufacture of the package 100 include fabricating the first conductive bumps 172 on the wafer of die 110. In alternative embodiments, the first conductive bumps 172 may be fabricated on the wafer of die 120. The processes further include placing the die 110 with associated RF shielding 150 over the die 120 using the first conductive bumps 172. Once the die 110 is in position, it is processed (for example, by reflow) to cause it to join to the die 120, then molding (for example, by vacuum) is performed to encapsulate the die 110 within the mold compound 170. After vacuum-molding, the vias 167 are formed, plated with the second conductive layer 175, and then bumped with the second conductive bumps 180. According to some example embodiments, the vias 167 are formed in the mold compound 170 by exposure to laser energy. At some point prior to singulation of the packages, the molded wafer may be background to achieve the package thicknesses mentioned above.

FIG. 2 is a sectional diagram illustrating various components of a stacked die package 200 according to a second example embodiment. The stacked die package 200 includes stacked die 210 and 220, each having die active circuitry 215 and 225, respectively. A first conductive pattern, which includes bump pads 265, is disposed on the die 220. The stacked die package 200 further includes a plating bus 260. As illustrated, the plating bus 260 is disposed in the saw street 205. The saw streets 205 are areas that will be subsequently cut to separate the package 200 from adjacent packages. The placement of the plating bus 260 in the saw streets 205 beneficially allows for the electroplating of high-aspect vias.

An RF shield 250, which shields RF die circuitry in the active circuitry 215 and 225 from each other, is disposed on a bottom surface of the die 210. First conductive bumps 272 are disposed such that the RF shield is spaced away from the active circuitry 225. The first conductive bumps 272 are disposed between bump pads 255 of the die 210 and bump pads 265 of the die 220.

The stacked die package 200 further includes a mold compound 270. Vias 267 penetrate the mold compound 270 to contact the plating bus 260, and studs 266 penetrate the mold compound 270 to contact the active circuitry 215. A second conductive pattern 275 is disposed on the mold compound 270, the vias 267, and the studs 266. Second conductive bumps 280 are disposed on the second conductive pattern 275. Relative to the stacked die package 100 of FIG. 1, fewer of the second conductive bumps 280 are required for the stacked die package 200 because the second conductive layer 275 is used to interconnect the die 210, 220.

As illustrated in FIG. 2, the stacked die package 200 is shown at the wafer level. That is, the die 220 is shown as integral to the neighboring dies 230, 240, prior to being separated from the neighboring dies along the saw streets 205. According to some embodiments, after separation from the neighboring dies 230, 240, the stacked die package 200 may be used as a flip chip die.

According to some embodiments, the thickness of package 200 is about 350 to about 400 microns thick, including the second conductive bumps 280. Since the vias 267 are not disposed through the die 210, the width of the die 210 should be less than the width of the die 220, so that a via 267 can penetrate to the first conductive layer 260 that is disposed on the die 220.

Processes employed in the manufacture of the package 200 include placing the die 210 with associated RF shielding 250 over the die 220 using the conductive bumps 252. Once the die 210 is in position, vacuum molding is performed to encapsulate the die 210 within the mold compound 270. After vacuum-molding, the vias 267 are formed, plated with the second conductive layer 275, and then bumped with the second conductive bumps 280. According to some example embodiments, the vias 267 are formed in the mold compound 270 by exposure to laser energy.

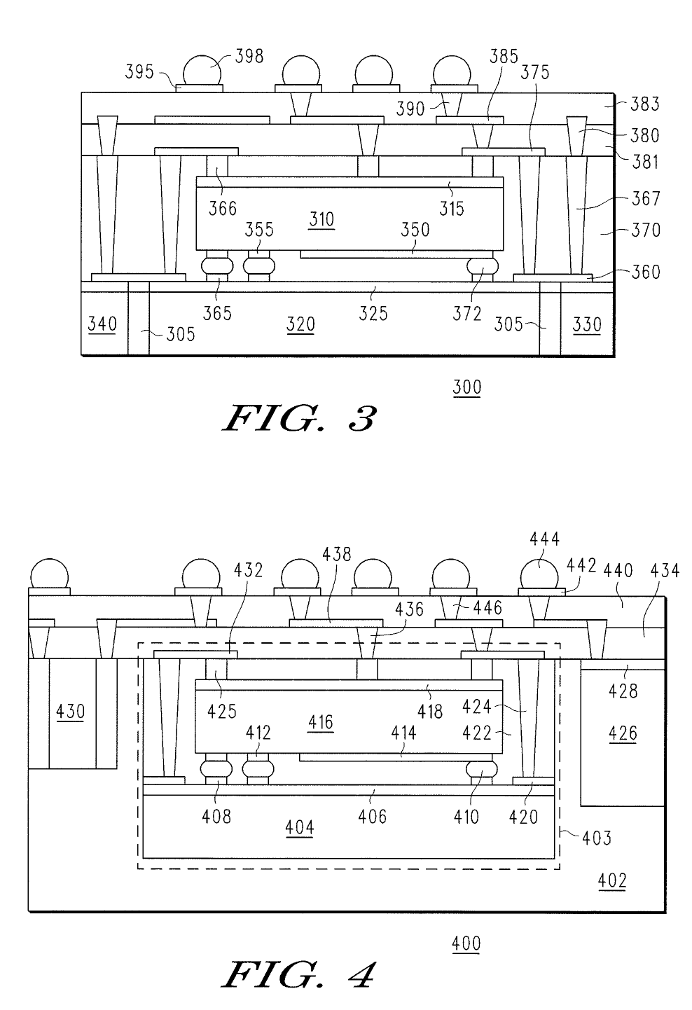

FIG. 3 is a sectional diagram illustrating various components of a stacked die package 300 according to a third example embodiment. The stacked die package 300 includes stacked die 310 and 320, each having die active circuitry 315 and 325, respectively. An RF shield 350, which shields RF die circuitry in the active circuitry 315 and 325 from each other, is disposed on a bottom surface of the die 310. First conductive bumps 372 are disposed such that the RF shield is spaced away from the active circuitry 325. The first conductive bumps 372 are disposed between bump pads 355 of the die 310 and bump pads 365 of the die 320 or the RF shield 350.

A first conductive pattern, which includes bump pads 365, is disposed on the die 320. The stacked die package 300 further includes a plating bus 360. The plating bus 360 is beneficially disposed in the saw streets 305 to allow for electroplating high aspect vias.

The stacked die package further includes a mold compound 370. Vias 367 penetrate the mold compound 370 to contact the first conductive pattern 360. Studs 366 penetrate the mold compound 370 to contact the active circuitry 315. A second conductive pattern 375 is disposed on the mold compound 370, the vias 367, and the studs 366.

The stacked die package 300 additionally includes a first Redistributed Chip Packaging (RCP) layer 381 and a second RCP layer 383 that are added at the wafer level. A third conductive pattern 385 is disposed on the first RCP layer 381, and a fourth conductive pattern 395 is disposed on the second RCP layer 383.

First RCP layer vias 380 penetrate the first RCP layer 381 to contact and electrically connect the third conductive pattern 385 to the second conductive pattern 375, while second RCP layer vias 390 penetrate the second RCP layer 383 to contact and electrically connect the fourth conductive pattern 395 to the third conductive pattern 385. Second conductive bumps 398 are disposed on the fourth conductive pattern.

In stacked die package 300, the presence of the first and second RCP layers 381, 383 and associated conductive structures eases bump pitch requirements, and also allows a complex interconnect structure that requires more than one layer and/or additional signal isolation structure.

In the example embodiment of FIG. 3, the active circuitry 325 is electrically connected to the active circuitry 315 by the plating bus 360, vias 367, and the second conductive pattern 375. The vias 367 are disposed through the mold compound 370, and the second conductive pattern 375 is disposed on the surface of the mold compound 370. The plating bus 360 is disposed in the saw street 305, and this beneficially allows for the electroplating of high-aspect vias.

As illustrated in FIG. 3, the stacked die package 300 is shown at the wafer level. That is, the die 320 is shown as integral to the neighboring dies 330, 340, prior to being separated from the neighboring dies along the saw streets 305. According to some embodiments, after separation from the neighboring dies 330, 340, the stacked die package 300 may be used as a flip chip die.

According to some embodiments, the thickness of package 300 is about 400 to about 500 microns thick, including the second conductive bumps 398. Since the vias 367 are not disposed through the die 310, the width of the die 310 should be less than the width of the die 320, so that some of the vias 367 can penetrate to the plating layer 360 that is disposed on the die 320.

Processes employed in the manufacture of the package 300 include placing the die 310 with associated RF shielding 350 over the die 320 using the first conductive bumps 372. Once the die 310 is in position, vacuum molding is performed to encapsulate the die 310 within the mold compound 370. After vacuum-molding, the vias 367 are formed and plated with the second conductive pattern 375. According to some example embodiments, the vias 365 are formed in the mold compound 370 by exposure to laser energy. The first RCP layer 381, the first RCP layer vias 380, the third conductive pattern 385, the second RCP layer 383, the second RCP layer vias 390, and the fourth conductive pattern 395 are subsequently formed using techniques that are known in the art.

FIG. 4 is a sectional diagram illustrating various components of a stacked die package 400 according to a fourth example embodiment. The stacked die package 400 includes stacked die 404 and 416, each having die active circuitry 406 and 418, respectively. An RF shield 414, which shields RF die circuitry in the active circuitry 406 and 418 from each other, is disposed on a bottom surface of the die 416. First conductive bumps 410 are disposed such that the RF shield 414 is spaced away from the active circuitry 406. The first conductive bumps 410 are disposed between bump pads 408 of the die 404 and bump pads 412 of the die 416.

A first conductive pattern 408 (for example, bump pads) is disposed on an upper surface of the active circuitry 406, as is a plating bus 420. A mold compound 422 encloses the die 416, and vias 424 penetrate the mold compound to contact the first conductive pattern 408. Studs 425 penetrate the mold compound 422 to contact the active circuitry 418.

A second conductive pattern 432 is disposed on the mold compound 422, the vias 424, and the studs 425. Signals from the active circuitry 406 are electrically connected to the second conductive pattern 432 by the vias 424 and the plating bus 420.

Elements 404-425 and 432 of package 400, which are shown grouped together as stacked die package 403, may be formed similar to the stacked package 300 of FIG. 3. Referring to FIG. 3, it can be seen that if the dies 320, 330, 340 were separated along the saw streets 305 prior to the wafer level formation of the first and second RCP layers 381, 383 and their associated conductive structures, the result would be the stacked die package 403 of FIG. 4. In the embodiments of FIG. 4, the stacked die packages 403 are used as “die” in the subsequent RCP process.

Returning to FIG. 4, the stacked die package 403 is disposed in RCP encapsulant 402, as is a single die 426 having active circuitry 428 and a discrete Surface Mount Technology (SMT) device 430. First and second RCP layers 434, 440 are disposed on the stacked die package 403, the single die 426, and the discrete SMT device 430. A third conductive pattern 438 is disposed on the first RCP layer 434 and a fourth conductive pattern 442 is disposed on the second RCP layer 440.

First RCP layer vias 436 penetrate the first RCP layer 434 to electrically connect the third conductive pattern 438 to the second conductive pattern 432, the discrete SMT device 430, and the active circuitry 428 of the single die 426. Second RCP layer vias 446 penetrate the second RCP layer 440 to electrically connect the fourth conductive pattern 442 to the third conductive pattern 438. Second conductive bumps 444 are disposed on the surface of the fourth conductive pattern 442. Like the stacked die package 300 of FIG. 3, the stacked die package 400 eases bump pitch requirements and allows complex interconnect structures that require more than one layer and/or additional signal isolation structures.

FIG. 5 is a sectional diagram illustrating various components of a stacked die package 500 according to a fifth example embodiment. The stacked die package 500 includes stacked die 506, 518, and 536, each having die active circuitry 508, 520, and 538, respectively. RF shields 516, 534 that shield RF die circuitry in the active circuitry 508, 520, 538 from each other, are disposed on a bottom surface of the die 518, 536, respectively.

A plating bus 522 is disposed on an upper surface of die 506, and over the saw street 503. A first conductive pattern 510 is also disposed on an upper surface of die 506. Similarly, portions of a second conductive pattern 528 serve as a plating bus for the second vias 540.

First vias 524 penetrate a first mold compound 526 to contact the first conductive pattern 522, while first studs 525 penetrate the first mold compound 526 to contact the active circuitry 520. Second conductive pattern 528 is disposed on the first vias 524, the first mold compound 526, and the first studs 525. Second vias 540 penetrate a second mold compound 542 to contact the second conductive pattern 528. Second studs 543 penetrate the second mold compound 542 to contact the active circuitry 538. The size of die 536 is constrained only by the size of the die 506, and the need to route signals up from die 506 and die 518.

Since the first vias 524 are not disposed through the die 518 and the second vias 540 are not disposed through the die 536, the width of the dies 518, 536 should be less than the width of the die 506, so that some of the vias 524, 540 can penetrate to the plating bus 522 or the second conductive pattern 528.

First conductive bumps 512 are disposed such that the RF shield 516 is spaced away from the active circuitry 508. The first conductive bumps 512 are disposed between bump pads 510 of the die 506 and bump pads 514 of the die 518 or the RF shield 516. Second conductive bumps 530 are disposed such that the RF shield 534 is spaced away from the active circuitry 520. The second conductive bumps 530 are disposed between the second conductive pattern 528 and bump pads 532 of the die 536 or the RF shield 534. The size of the second bumps 530 may be different than the size of the first bumps 512, and the thickness of die 536 may be different than the thickness of die 518 or die 506. The stacked die package 500 is fabricated in a manner that is similar to the stacked die package 200 of FIG. 2, except that the molding and interconnection process is repeated for each additional die that is disposed in the stacked die package.

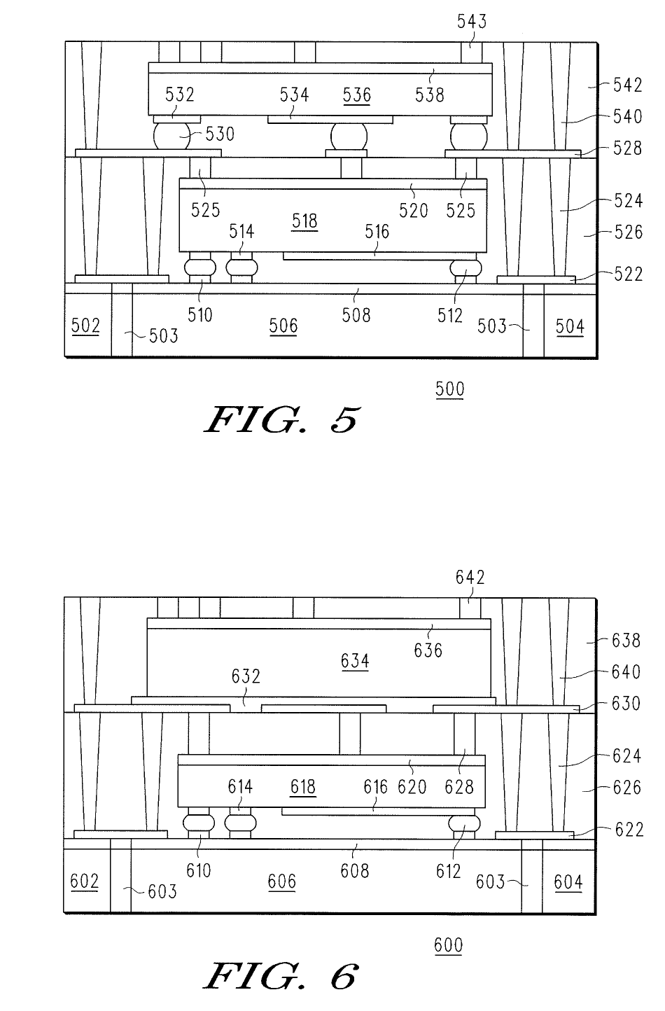

FIG. 6 is a sectional diagram illustrating various components of a stacked die package 600 according to a sixth example embodiment. The stacked die package 600 includes stacked die 606, 618, 634, each having die active circuitry 608, 620, 636, respectively. RF shield 616 that shields RF die circuitry in the active circuitry 608, 620 from each other is disposed on a bottom surface of the die 618. In alternative embodiments, there may also be an RF shield disposed between the active circuitry 620 and the active circuitry 636. For example, an RF shield may be formed in the conductive layer 630.

A first conductive pattern 610 is disposed on an upper surface of the die 606, and a plating bus 622 is disposed on an upper surface of die 606, over the saw street 603. First studs 628 penetrate a first mold compound 626 to contact the active circuitry 620. First vias 624 penetrate the first mold compound 626 to contact the plating bus 622.

Second conductive pattern 630 is disposed on the first vias 624, the first mold compound 626, and the first studs 628. Second vias 640 penetrate a second mold compound 638 to contact the second conductive pattern 630. Second studs 642 penetrate the second mold compound 638 to contact the active circuitry 636. The size of die 634 is constrained only by the size of the die 606, and the need to route signals up from die 606 and 618.

Since the first vias 624 are not disposed through the die 618 and the second vias 640 are not disposed through the die 634, the width of the dies 618, 634 should be less than the width of the die 606, so that some of the vias 624, 640 can penetrate to the plating bus 622 or the second conductive layer 630.

In the stacked die package 600, the die 634 is attached to the first mold compound 626 and the second conductive pattern 630 using a die attach material 632. The die attach material 632 may be, for example, an adhesive layer.

In the stacked die package 600, because the first studs 628 are sufficiently tall, the active circuitry 620 and the active circuitry 636 are separated enough such that it is not necessary to use bumps or an RF shield between the die 618 and the die 634.

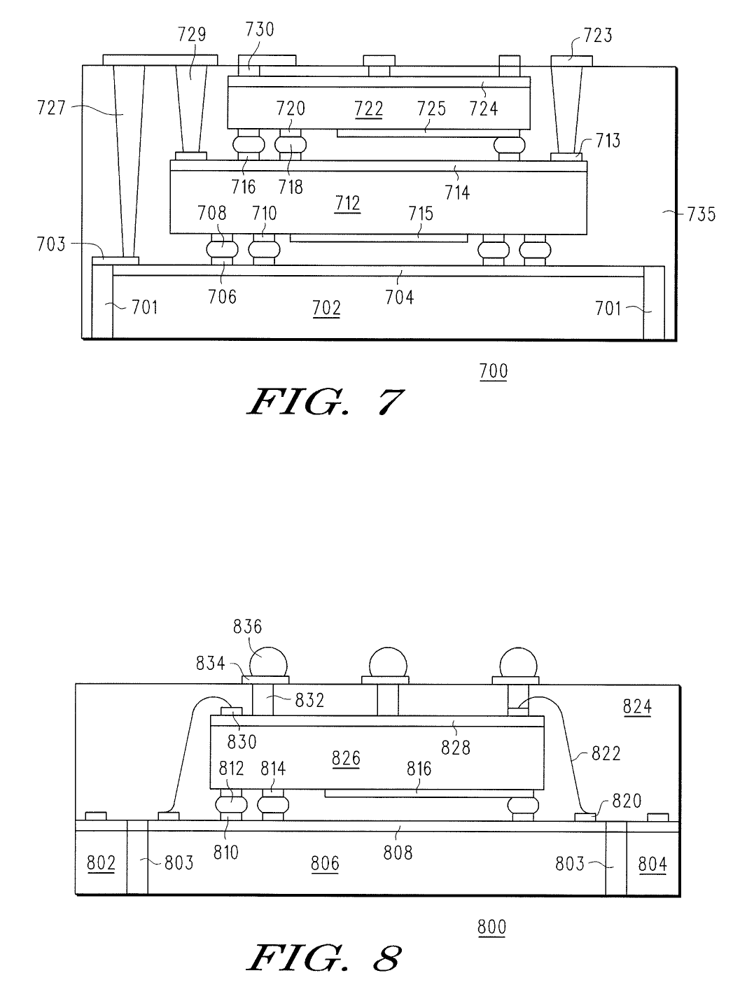

FIG. 7 is a sectional diagram illustrating various components of a stacked die package 700 according to a seventh example embodiment. The stacked die package 700 includes stacked die 702, 712, 722, each having die active circuitry 704, 714, 724, respectively. RF shields 715, 725 are disposed on the underside of die 712, 722, respectively.

A first conductive pattern 706 is disposed on the die 702, a second conductive pattern 713 is disposed on the die 712, and a third conductive pattern 723 is disposed on a mold compound 735, which surrounds and protects the die 702, 712, 722. A plating bus 703 is disposed in the saw street 701.

First conductive bumps 708 are disposed between the die 702 and 712, while second conductive bumps 718 are disposed between the die 712 and 722. The conductive bumps 708, 718 provide additional separation between the active circuitry 704, 714, 724 on each of the die 702, 712, 722. The conductive bumps 708 are attached to the first conductive pattern 706 on the upper surface of the die 702 and to bump pads 710 on the lower surface of the die 712. The conductive bumps 718 are attached to bump pads 716 on the upper surface of the die 712 and to bump pads 720 on the lower surface of the die 722, or to the RF shield 725 on the lower surface of the die 722.

A via 727 penetrates the mold compound 735 to contact the plating bus 703. Vias 729 penetrate the mold compound 735 to contact the second conductive pattern 713, and studs 730 penetrate the mold compound 735 to contact the active circuitry 724.

According to the embodiment illustrated in FIG. 7, two or more die can be stacked concurrently, as opposed to the embodiment of, for example, FIG. 5, where the molding and interconnection process are sequentially repeated for each die. However, when the die are stacked in this manner, the width of the die should become successively smaller as one moves up the stack in order to allow for interconnection. This is illustrated in FIG. 7, where the die 712 is wider than the die 722, and the die 702 is in turn wider than the die 712. In stacked die package 700, the second conductive layer 713 is not disposed in the saw street 701. Note also that, in this embodiment, there is no plating bus in the conductive layer 716 to assist in plating the upper vias 729.

Using laser etching techniques, the vias 727, 729 and the studs 730 may be formed at substantially the same time. Subsequently, the third conductive layer 723 is formed in contact with the via 727, the vias 729, and the studs 730.

In each of the stacked die packages 100-700 illustrated in FIGS. 1-7, the signals from the bottom die were brought to the top of the package using plated vias in the encapsulant. This approach uses relatively high-aspect microvias in the encapsulant, as well as relatively large capture pads on the bottom die. According to some other example embodiments, wirebonding techniques may be used to bring the Input/Output (I/O) signals from the bottom die to the top of the package, which may result in reduced process development and further reductions in the size of the RF modules. FIGS. 8-14 illustrate example embodiments that take advantage of wirebonding techniques.

FIG. 8 is a sectional diagram illustrating various components of a stacked die package 800 according to an eighth example embodiment. The stacked die package 800 is similar to the stacked die package 100 of FIG. 1, but uses wirebonding techniques rather than vias through the encapsulant.

The stacked die package 800 includes stacked die 806 and 826, each having die active circuitry 808 and 828, respectively. An RF shield 816, which shields RF die circuitry in the active circuitry 808 and 825 from each other, is disposed on a bottom surface of the die 826. First conductive bumps 812 are disposed such that the RF shield 816 is spaced away from the active circuitry 808. The first conductive bumps 812 are disposed between bump pads 810 of the die 806 and bump pads 814 of the die 826 or the RF shield 816.

The stacked die package 800 includes a first conductive pattern 820 that is disposed on the die 806. Compared to the stacked die package 100 of FIG. 1, the first conductive pattern 820 is not disposed in the saw street 803.

The stacked die package 800 further includes a mold compound 824. Studs 832 penetrate the mold compound 824 to contact the active circuitry 828. Furthermore, I/O signals from the bottom die 806 are routed to the top of the package using wirebonds 822 that connect the first conductive pattern 820 disposed on the active circuitry 808 to a second conductive pattern 830 that is disposed on the active circuitry 828. The first and second conductive patterns 820, 830 may be, for example, wirebond pads. Second conductive bumps 836 are disposed on a third conductive pattern 834, which is in contact with the studs 832.

As illustrated in FIG. 8, the stacked die package 800 is shown at the wafer level. That is, the die 806 is shown as integral to the neighboring dies 802, 804 prior to being separated or singulated from the neighboring dies along the saw streets 803. After singulation, the stacked die package 800 may be used as a flip chip die.

The thickness of package 800 is about 350 to about 400 microns thick, including the second conductive bumps 836. The width of die 826 should be less than the width of die 806 so that there is space for the wirebonds 822 to contact the first conductive pattern 820.

Processes employed in the manufacture of the package 800 include placing the die 826 with associated RF shielding 816 over the die 806 using the first conductive bumps 812 and reflowing to join them. A wirebonding process is then performed to connect the first conductive pattern 820 to the second conductive pattern 830. Next, vacuum molding is preformed to encapsulate the die 826 within the mold compound 824. The studs 832 that contact the active circuitry 828 are then formed in the mold compound 824, followed by the third conductive pattern 834 that is in contact with the studs 832. Next, the second conductive bumps 836 are formed on the third conductive pattern 834. The second conductive bumps 836 are disposed in an area directly above the die 826.

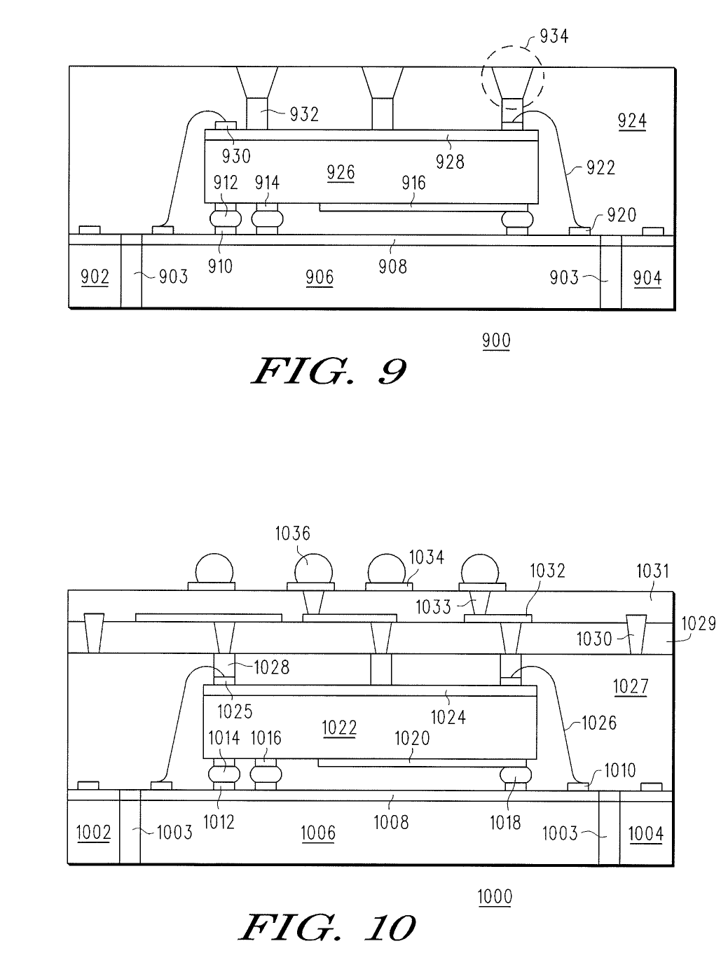

FIG. 9 is a sectional diagram illustrating various components of a stacked die package 900 according to a ninth example embodiment. The stacked die package 900 is similar to the stacked die package 800 of FIG. 8, but is able to achieve a larger clearance between the wirebonds and the top of the package, without increasing stud height. This will be explained in further detail below.

The stacked die package 900 includes stacked die 906 and 926, each having die active circuitry 908 and 928, respectively. An RF shield 916, which shields RF die circuitry in the active circuitry 908 and 928 from each other, is disposed on a bottom surface of the die 926. First conductive bumps 912 are disposed such that the RF shield 916 is spaced away from the active circuitry 908. The first conductive bumps 912 are disposed between bump pads 910 of the die 906 and bump pads 914 of the die 926 or the RF shield 916.

The stacked die package 900 includes a first conductive pattern 920 that is disposed on the die 906. The stacked die package 900 further includes a mold compound 924. Studs 932 penetrate the mold compound 924 to contact the active circuitry 928. Furthermore, I/O signals from the bottom die 906 are routed to the top of the package using wirebonds 922 that connect the first conductive pattern 920 disposed on the active circuitry 908 to a second conductive pattern 930 that is disposed on the active circuitry 928. The first and second conductive patterns 920, 930 may be, for example, wirebond pads.

As illustrated in FIG. 9, the stacked die package 900 is shown at the wafer level. That is, the die 906 is shown as integral to the neighboring dies 902, 904 prior to being separated or singulated from the neighboring dies along the saw streets 903. After singulation, the stacked die package 900 may be used as a flip chip die.

The processes employed in a method of fabricating the stacked die package 900 are similar to the processes that were described above the stacked die package 800, with the following deviation. As shown in FIG. 9, the studs 932 are exposed by holes 934 in the mold compound 924. The holes 934 may be formed using, for example, laser energy. Thus, the studs 932 are exposed without placing undue stress on them.

Subsequently, second conductive bumps (not shown) are formed within the holes 934. The formation of the holes 934 allows a larger clearance between the wirebonds 922 and the top surface of the mold compound 924, without increasing the height of the studs 932.

FIG. 10 is a sectional diagram illustrating various components of a stacked die package 1000 according to a tenth example embodiment. The stacked die package 1000 is similar to the stacked die package 300 of FIG. 3, but uses wirebonds instead of vias to bring signals from the bottom die to the top of the mold compound. This feature is explained in further detail below.

The stacked die package 1000 includes stacked die 1006 and 1022, each having die active circuitry 1008 and 1024, respectively. An RF shield 1020, which shields RF die circuitry in the active circuitry 1008 and 1024 from each other, is disposed on a bottom surface of the die 1022. First conductive bumps 1014 are disposed such that the RF shield 1020 is spaced away from the active circuitry 1008. The first conductive bumps 1014 are disposed between bump pads 1012 of the die 1006 and bump pads 1016 of the die 1022 or the RF shield 1020.

The stacked die package 1000 includes a first conductive pattern 1010 that is disposed on the die 1006. The stacked die package 1000 further includes a mold compound 1027 that surrounds and encloses the die 1022. Studs 1028 penetrate the mold compound 1027 to contact the active circuitry 1024 of the upper die 1022. Furthermore, I/O signals from the bottom die 1006 are routed to the top of the package using wirebonds 1026 that connect the first conductive pattern 1010 disposed on the active circuitry 1008 to a second conductive pattern 1025 that is disposed on the active circuitry 1024. The first and second conductive patterns 1010, 1025 may be, for example, wirebond pads.

The stacked die package 1000 further includes a first RCP layer 1029 and a second RCP layer 1031 that are added at the wafer level. The first and second RCP layers 1029, 1031 are disposed on the mold compound 1027. A third conductive pattern 1032 is disposed on the first RCP layer 1029 and a fourth conductive pattern 1034 is disposed on the second RCP layer 1031. First RCP layer vias 1030 penetrate the first RCP layer 1029 to contact the studs 1028. The third conductive pattern 1032 is disposed in contact with the first RCP layer vias 1030. Second RCP layer vias 1033 penetrate the second RCP layer 1031 to contact the third conductive pattern 1032. The fourth conductive pattern 1034 is disposed in contact with the second RCP layer vias 1033.

In stacked die package 1000, the presence of the first and second RCP layers 1029, 1031 and associated conductive structures eases bump pitch requirements, and also allows for a complex interconnect structure that requires more than one layer and/or additional signal isolation structures.

As illustrated in FIG. 10, the stacked die package 1000 is shown at the wafer level. That is, the die 1006 is shown as integral to the neighboring dies 1002, 1004 prior to being separated or singulated from the neighboring dies along the saw streets 1003. After singulation, the stacked die package 1000 may be used as a flip chip die.

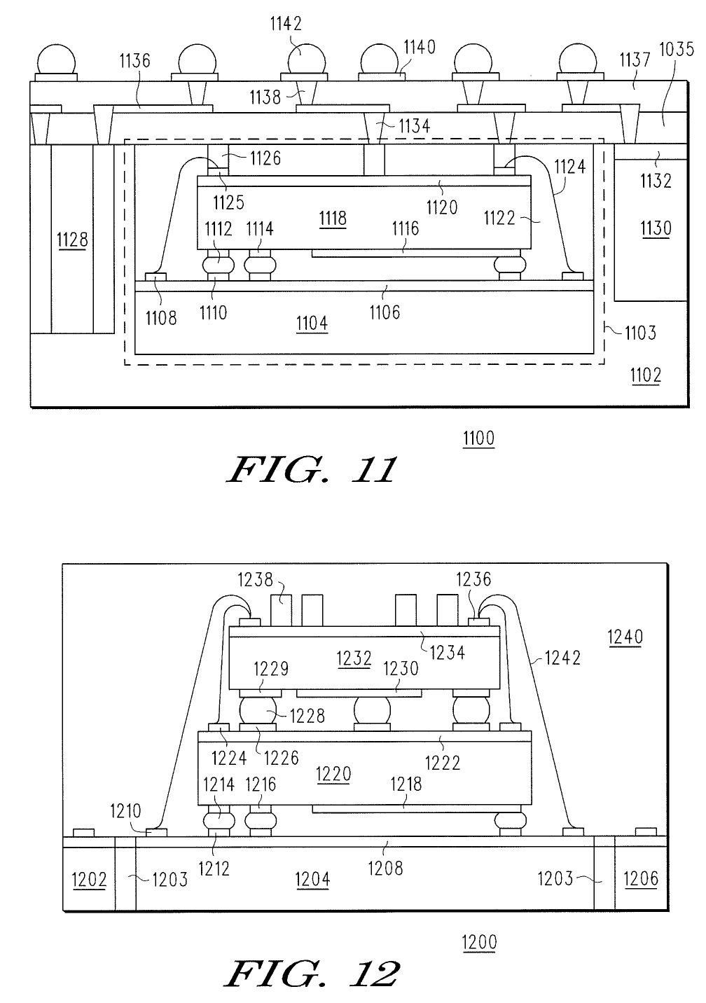

FIG. 11 is a sectional diagram illustrating various components of a stacked die package 1100 according to an eleventh example embodiment. The stacked die package 1100 is similar to the stacked die package 400 of FIG. 4, but uses wirebonds instead of vias to bring signals from the bottom die to the top of the mold compound. This feature is explained in further detail below.

The stacked die package 1100 includes stacked die 1104 and 1118, each having die active circuitry 1106 and 1120, respectively. An RF shield 1116, which shields RF die circuitry in the active circuitry 1106 and 1120 from each other, is disposed on a bottom surface of the die 1118. First conductive bumps 1112 are disposed such that the RF shield 1116 is spaced away from the active circuitry 1106. The first conductive bumps 1112 are disposed between bump pads 1110 of the die 1104 and bump pads 1114 of the die 1118 or the RF shield 1116.

A first conductive pattern 1108 is disposed on an upper surface of the active circuitry 1106. A mold compound 1122 encloses the die 1118, and studs 1126 penetrate the mold compound to contact the active circuitry 1120.

A second conductive pattern 1125 is disposed on the mold compound 1122 and the studs 1126. Wirebonds 1124 contact the first conductive pattern 1108 and the second conductive pattern 1125. In this embodiment, the first and second conductive patterns 1108, 1125 include wirebond pads. Signals from the active circuitry 1106 are routed to the second conductive pattern 1125 through the first conductive pattern 1108 and the wirebonds 1124.

Elements 1104-1126 of package 1100, which are shown grouped together as stacked die package 1103, may be formed similar to the stacked package 800 of FIG. 8. Referring to FIG. 8, it can be seen that if the dies 802, 804, 806 were separated along the saw streets 803 prior to the formation of the third conductive pattern 834 and the second conductive bumps 836, the result would be the stacked die package 1103 of FIG. 11. In the embodiments of FIG. 11, the stacked die packages 1103 are used as “die” in the subsequent RCP process.

Returning to FIG. 11, the stacked die package 1103 is disposed in RCP encapsulant 1102, as is a single die 1130 having active circuitry 1132 and a discrete SMT device 1128. First and second RCP layers 1135, 1137 are disposed on the stacked die package 1103, the single die 1130, and the discrete SMT device 1128. A third conductive pattern 1136 is disposed on the first RCP layer 1135 and a fourth conductive pattern 1140 is disposed on the second RCP layer 1137.

First RCP layer vias 1134 penetrate the first RCP layer 1135 to electrically connect the third conductive pattern 1136 to the studs 1126, the discrete SMT device 1128, and the active circuitry 1132 of the single die 1130. Second RCP layer vias 1138 penetrate the second RCP layer 1137 to electrically connect the fourth conductive pattern 1140 to the third conductive pattern 1136. Second conductive bumps 1142 are disposed on the surface of the fourth conductive pattern 1140.

Like the stacked die package 1000 of FIG. 10, the stacked die package 1100 eases bump pitch requirements and allows complex interconnect structures that require more than one layer and/or additional signal isolation structures.

FIG. 12 is a sectional diagram illustrating various components of a stacked die package 1200 according to a twelfth example embodiment. The stacked die package 1200 is similar to the stacked die package 500 of FIG. 5, but uses wirebonds instead of vias to bring signals from the bottom die to the top of the package. This feature is explained in further detail below.

The stacked die package 1200 includes stacked die 1204, 1220, 1232, each having die active circuitry 1208, 1222, 1234, respectively. RF shields 1218, 1230 that shield RF die circuitry in the active circuitry 1208, 1222, 1234 from each other, are disposed on a bottom surface of the die 1220, 1232, respectively.

A first conductive pattern 1210 is disposed on an upper surface of die 1204. A second conductive pattern 1224 is disposed on an upper surface of die 1220, and a third conductive pattern 1236 is disposed on an upper surface of the die 1232. Wirebonds 1242 connect the first conductive pattern 1210 and the second conductive pattern 1224 to the third conductive pattern 1236. In this embodiment, the first, second, and third conductive patterns 1210, 1224, and 1236 include wirebond pads.

First conductive bumps 1214 are disposed such that the RF shield 1218 is spaced away from the active circuitry 1208. The first conductive bumps 1214 are disposed between bump pads 1212 of the die 1204 and bump pads 1216 of the die 1220 or the RF shield 1218. Second conductive bumps 1228 are disposed such that the RF shield 1230 is spaced away from the active circuitry 1222. The second conductive bumps 1228 are disposed between bump pads 1226 of the die 1220 and bump pads 1229 of the die 1232 or the RF shield 1230. The size of the second bumps 1228 may be different than the size of the first bumps 1214, and the thickness of die 1232 may be different than the thickness of die 1220 or die 1204.

Studs 1238 are disposed in contact with the active circuitry 1234 of die 1232. A mold compound 1240 surrounds the dies 1220, 1232. The mold compound 1240 may be subsequently planarized to expose the studs 1238.

In package 1200, the size of die 1232 is constrained only by the size of the die 1220, and the need to route signals up from die 1204 and die 1220. That is, the width of the die 1232 should be less than the width of the die 1220, so that the wirebonds 1242 connecting the dies 1232 and 1220 are within the area defined by the die 1220. Similarly, the width of the die 1220 should be less than the width of the die 1204, so that the wirebonds 1242 connecting the dies 1204 and 1232 are within the area defined by the die 1204.

According to an alternative embodiment, the width of the top die 1232 may be greater than the width of the middle die 1220, yet less than the width of the bottom die 1204. In this case, wirebonds would exist between the middle die 1220 and the bottom die 1204 so that signals from the middle die 1220 would first be routed to the bottom die 1204 before being sent to the top die 1232.

As illustrated in FIG. 12, the stacked die package 1200 is shown at the wafer level. That is, the die 1204 is shown as integral to the neighboring dies 1202, 1206 prior to being separated or singulated from the neighboring dies along the saw streets 1203. After singulation, the stacked die package 1200 may be used as a flip chip die.

FIG. 13 is a sectional diagram illustrating various components of a stacked die package 1300 according to a thirteenth example embodiment. The stacked die package 1300 includes die 1318 and dummy die 1332, which are stacked upon die 1304. Die 1304 and die 1318 have active die circuitry 1308 and 1320, respectively. An RF shield 1316 is disposed on an underside of the die 1318, and shields active RF circuitry in active circuitry 1308 and 1320 from each other.

Dummy die 1332 has no active circuitry and is used only for I/O transfer. If dummy die 1332 has no shielding requirement, it may be attached directly to the bottom die 1304 using a non-conductive adhesive 1334, as shown. In alternative embodiments, the dummy die 1332 may constitute an Integrated Passive Device (IPD) that includes passive circuit elements.

A first conductive pattern 1322 is disposed on the die 1304. A second conductive pattern 1324 is disposed on the die 1318 and the dummy die 1332. Wirebonds 1338 connect the first conductive pattern 1322 to the second conductive pattern 1324. In this embodiment, the first and second conductive patterns 1322, 1324 include wirebond pads.

Conductive bumps 1312 are disposed such that the RF shield 1316 is spaced apart from the active circuitry 1308. The conductive bumps 1312 are disposed between bump pads 1310 disposed on the die 1304 and bump pads 1314 disposed on the underside of the die 1318, or disposed between the bump pads 1314 and the RF shield 1316.

Studs 1326 are disposed on top of the die 1318 and the dummy die 1332, and are electrically connected to the second conductive pattern 1324. A molding compound 1336 is disposed on the die 1304 and encloses the other structures disposed on the die 1304. Holes 1330 expose top surfaces of the studs 1326.

FIG. 13 illustrates the stacked die package 1300 at an intermediate stage of fabrication, after the holes 1330 have been formed but before conductive bumps have been formed in the holes 1330 to contact the studs 1326. As illustrated in FIG. 13, the stacked die package 1300 is shown at the wafer level. That is, the die 1304 is shown as integral to the neighboring dies 1302, 1306 prior to being separated or singulated from the neighboring dies along the saw streets 1303. After singulation, the stacked die package 1300 may be used as a flip chip die.

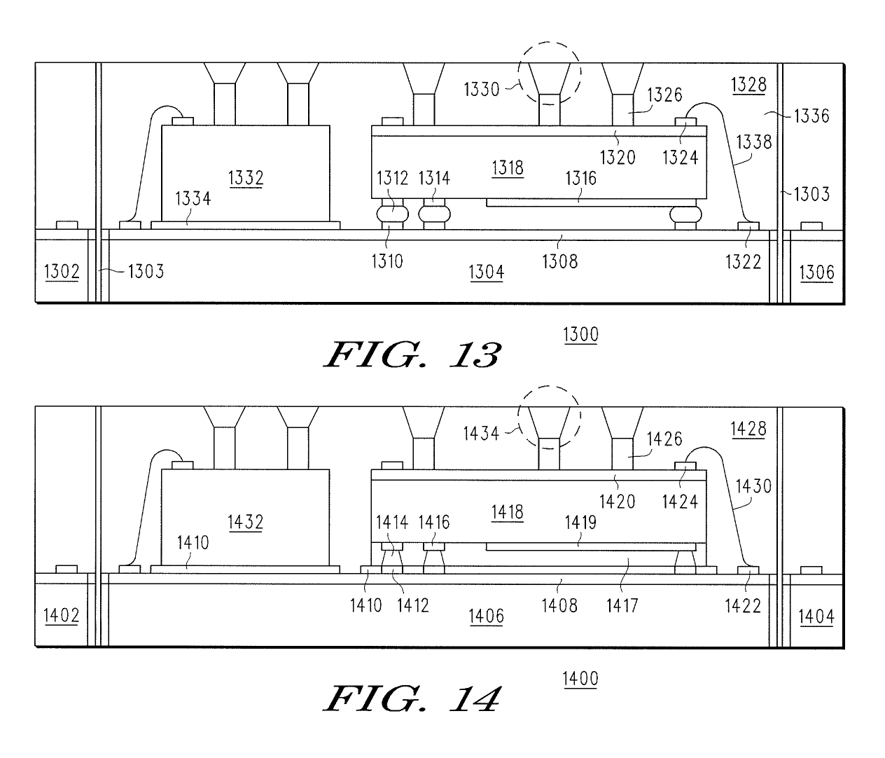

FIG. 14 is a sectional diagram illustrating various components of a stacked die package 1400 according to a fourteenth example embodiment. The stacked die package 1400 is similar to the stacked die package 1300 of FIG. 13, but uses flex rather than conductive bumps to space the top dies from the bottom die. This feature will be explained in further detail below.

The stacked die package 1400 includes die 1418 and dummy die 1432, which are stacked upon bottom die 1406. Die 1406 and die 1418 have active die circuitry 1408 and 1420, respectively. An RF shield 1419 is disposed on an underside of the die 1418, and shields active RF circuitry in active circuitry 1408 and 1420 from each other.

Dummy die 1432 has no active circuitry and is used only for I/O transfer. Since dummy die 1432 has no shielding requirement, it may be attached directly to the bottom die 1406 using a non-conductive adhesive 1410, as shown. In alternative embodiments, the dummy die 1432 may constitute an Integrated Passive Device (IPD) that includes passive circuit elements.

A first conductive pattern 1422 is disposed on the die 1406. A second conductive pattern 1424 is disposed on the die 1418 and the dummy die 1432. Wirebonds 1430 connect the first conductive pattern 1422 to the second conductive pattern 1424. In this embodiment, the first and second conductive patterns 1422, 1424 include wirebond pads.

To space the top die 1418 from the bottom die 1406, a flexible substrate (flex) 1417 is disposed between the top die and the bottom die. The flex 1417 is attached to the bottom die 1406 using a layer of anisotropic-conductive adhesive 1410, or alternatively by using solder. Conductive vias 1414 in the flex 1417 electrically connect pads 1412 disposed on the die 1406 to pads 1416 disposed on the underside of the die 1418.

According to alternative example embodiments, if there were no shielding requirement present, the RF shield 1419 and flex 1417 could be eliminated. In this case, the die 1418 could be attached directly to the die 1406 using the non-conductive adhesive 1410.

Studs 1426 are disposed on top of the die 1418 and the dummy die 1432, and are electrically connected to the second conductive pattern 1424. A molding compound 1428 is disposed on the die 1406 and encloses the other structures disposed on the die 1406. Holes 1434 expose top surfaces of the studs 1426.

FIG. 14 illustrates the stacked die package 1400 at an intermediate stage of fabrication, after the holes 1434 have been formed but before conductive bumps have been formed in the holes 1434 to contact the studs 1426. As illustrated in FIG. 14, the stacked die package 1400 is shown at the wafer level. That is, the die 1406 is shown as integral to the neighboring dies 1402, 1404 prior to being separated or singulated from the neighboring dies along the saw streets 1403. After singulation, the stacked die package 1400 may be wire-bonded, bumped, or used as an RCP die or a flip-chip die.

Some of the packages 100-1400 illustrated in FIGS. 1-14 include stacked, shielded, interconnected die that may be wire-bonded, bumped, or used in a subsequent RCP process. In the packages 800-1400, signals are effectively routed to the top die, and then extracted from the top die by some other means, such as copper stud. According to some embodiments, such as those illustrated in FIGS. 1-7, vias are formed in the encapsulant material, rather than in the semiconductors, to interconnect the dies. According to some other embodiments, such as those illustrated in FIGS. 8-14, wirebonds are used to interconnect the dies. In alternative embodiments, a combination of vias through the encapsulant and wirebonding techniques may be used.

It should be emphasized that while the embodiments described above include RF shields, the invention is not so limited. The inventive aspects found in one or more of the embodiments described above may just as easily be applied to stacked die packages that do not have RF shielding requirements. Furthermore, the invention may be practiced in many ways. What follows are exemplary, non-limiting descriptions of example embodiments.

According to an example embodiment, a method of fabricating a stacked die package includes the steps of stacking at least a second die with second active circuitry on a first die having first active circuitry, forming a first conductive pattern on the first active circuitry, and encapsulating the second die in a mold compound that is disposed on the first die. The method further includes forming a first electrical connection in the mold compound that electrically contacts the first conductive pattern, forming a second electrical connection in the mold compound that contacts the second active circuitry, and forming a second conductive pattern on the mold compound that electrically contacts the first electrical connection and the second electrical connection. Stacking at least the second die on the first die may include stacking the second die on a wafer, the wafer including the first die and a third die. The method may further include forming a plating bus in a saw street between the first die and the third die, and sawing along the saw street to singulate the stacked die package from the wafer and to at least partially remove the plating bus.

According to an example embodiment, stacking the second die on the wafer includes attaching a Radio Frequency (RF) shield to a lower surface of the second die, positioning at least one conductive bump on the wafer and above the first die, and positioning the second die on the at least one conductive bump such that the RF shield is in electrical contact with a grounding point of the first die through the one conductive bump. Stacking the second die on the wafer may also include attaching a Radio Frequency (RF) shield to a lower surface of the second die, positioning a flexible substrate on the wafer in a region above the first die, the flexible substrate having at least two conductive vias, and positioning the second die on the flexible substrate such that the RF shield is in electrical contact with a grounding point of the first die through one of the at least two conductive vias.

According to an example embodiment, forming the first electrical connection in the mold compound includes forming a first via that penetrates the mold compound to physically contact the first conductive pattern. Forming the second electrical connection in the mold compound may include forming a second via that penetrates the mold compound to physically contact the second active circuitry. The method may further include forming a third conductive pattern on the second active circuitry.

According to an example embodiment, forming the first electrical connection in the mold compound comprises wirebonding the first conductive pattern to the third conductive pattern prior to encapsulating the second die in the mold compound. Forming the second electrical connection in the mold compound may include forming a first via that penetrates the mold compound to physically contact the second active circuitry.

According to an example embodiment, a stacked die package includes a first die, first active circuitry disposed on an upper surface of the first die, and a first conductive pattern disposed on the first active circuitry, where the first conductive pattern is electrically connected to the first active circuitry. The stacked die package further includes a second die disposed over the first die, where the first die is wider than the second die, second active circuitry disposed on an upper surface of the second die, and a mold compound disposed on the first die, where the mold compound encapsulates the second die. The stacked die package further includes a second conductive pattern disposed on the mold compound, the second conductive pattern electrically connected to the second active circuitry, and a first via that penetrates the mold compound, an upper end of the first via in contact with the second conductive pattern, a lower end of the first via in contact with the first conductive pattern.

According to an example embodiment, the stacked die package further includes a Radio Frequency (RF) shield disposed on a bottom surface of the second die, the RF shield grounded by an electrical connection to the first active circuitry, and conductive bumps disposed between the second die and the first die, the conductive bumps separating the RF shield from the first active circuitry, the electrical connection including at least one of the conductive bumps. The stacked die package may further include a Radio Frequency (RF) shield disposed on a bottom surface of the second die, the RF shield grounded by an electrical connection to the first active circuitry, a flexible substrate disposed between the second die and the first die, the flexible substrate separating the RF shield from the first active circuitry, and a second via that penetrates the flexible substrate, the electrical connection including the second via.

According to an example embodiment, the stacked die package further includes a dielectric layer disposed on the mold compound and the second conductive pattern, and a second via that penetrates the dielectric layer to contact the second conductive pattern. The stacked die package may further include a third die disposed over the second die, the third die encapsulated by the dielectric layer, a width of the third die less than a width of the first die.

According to an example embodiment, a stacked die package includes a first die, first active circuitry disposed on an upper surface of the first die, a first conductive pattern disposed on the first active circuitry, and a second die disposed over the first die, where the first die is wider than the second die in a cross-section of the stacked die package. The stacked die package further includes second active circuitry disposed on an upper surface of the second die, a second conductive pattern disposed on the second active circuitry, a first wirebond that connects the first conductive pattern to the second conductive pattern, and a mold compound disposed on the first die, the mold compound encapsulating the second die and the wirebond.

According to an example embodiment, the stacked die package further includes a third die disposed on the first die and arranged adjacent to the second die, a third conductive pattern disposed on an upper surface of the third die, and a second wirebond that connects the first conductive pattern to the third conductive pattern, the mold compound encapsulating the third die and the second wirebond. The stacked die package may further include a third die disposed between the first die and the second die, third active circuitry disposed on an upper surface of the third die, a third conductive pattern disposed on the third active circuitry, and a second wirebond that connects the third conductive pattern to the second conductive pattern, the mold compound encapsulating the third die and the second wirebond.

According to an example embodiment, the stacked die package further includes a conductive stud that penetrates the mold compound to contact the second active circuitry, a dielectric layer disposed on the mold compound and the conductive stud, and a first via that penetrates the dielectric layer to contact the conductive stud. The stacked die package may further include an RF shield disposed on a bottom surface of the second die.

While at least one example embodiment has been presented in the foregoing detailed description, it should be appreciated that a vast number of variations exist, especially with respect to choices of device types and materials and the sequence of processes. The example embodiments described above are especially useful for the shielding of active RF circuits in semiconductor modules while minimizing the size of the RF module, but persons of skill in the art will understand based on the description herein that other types of devices may be improved using the concepts taught herein. For example, the inventive principles found in the example embodiments could be applied to other devices that require shielding of active circuits within a limited amount of space. Furthermore, the teachings of the example embodiments may be applied to other devices that do not have a shielding requirement.

It should be emphasized that the example embodiments described above are only examples, and are not intended to limit the scope, applicability, or configuration of the invention in any way. Rather, the detailed description of the example embodiments provides those skilled in the art with a convenient road map for implementing the inventive principles contained in the example embodiments. The subject matter of the invention includes all combinations and subcombinations of the various elements, features, functions and/or properties disclosed herein. It also should be understood that various changes can be made in the function and arrangement of elements without departing from the scope of the invention as set forth in the appended claims and the legal equivalents thereof.

1. A method of fabricating a stacked die package comprising the steps of:
stacking at least a second die with second active circuitry on a first die having first active circuitry;
forming a first conductive pattern on the first active circuitry;
encapsulating the second die in a mold compound that is disposed on the first die;
forming a first electrical connection in the mold compound that electrically contacts the first conductive pattern;
forming a second electrical connection in the mold compound that contacts the second active circuitry; and
forming a second conductive pattern on the mold compound that electrically contacts the first electrical connection and the second electrical connection.

2. The method of claim 1, wherein stacking at least the second die on the first die comprises stacking the second die on a wafer, the wafer including the first die and a third die.

3. The method of claim 2, further comprising:
forming a plating bus in a saw street between the first die and the third die; and
sawing along the saw street to singulate the stacked die package from the wafer and to at least partially remove the plating bus.

4. The method of claim 2, wherein stacking the second die on the wafer comprises:
attaching a Radio Frequency (RF) shield to a lower surface of the second die;
positioning at least one conductive bump on the wafer and above the first die; and
positioning the second die on the at least one conductive bump such that the RF shield is in electrical contact with a grounding point of the first die through the one conductive bump.

5. The method of claim 2, wherein stacking the second die on the wafer comprises:
attaching a Radio Frequency (RF) shield to a lower surface of the second die;
positioning a flexible substrate on the wafer in a region above the first die, the flexible substrate having at least two conductive vias; and
positioning the second die on the flexible substrate such that the RF shield is in electrical contact with a grounding point of the first die through one of the at least two conductive vias.

6. The method of claim 1, wherein forming the first electrical connection in the mold compound comprises forming a first via that penetrates the mold compound to physically contact the first conductive pattern.

7. The method of claim 6, wherein forming the second electrical connection in the mold compound comprises forming a second via that penetrates the mold compound to physically contact the second active circuitry.

8. The method of claim 1, further comprising forming a third conductive pattern on the second active circuitry.

9. The method of claim 8, wherein forming the first electrical connection in the mold compound comprises wirebonding the first conductive pattern to the third conductive pattern prior to encapsulating the second die in the mold compound.

10. The method of claim 9, wherein forming the second electrical connection in the mold compound comprises forming a first via that penetrates the mold compound to physically contact the second active circuitry.

11. A stacked die package comprising:
a first die;
first active circuitry disposed on an upper surface of the first die;
a first conductive pattern disposed on the first active circuitry, the first conductive pattern electrically connected to the first active circuitry;
a second die disposed over the first die, the first die wider than the second die;
second active circuitry disposed on an upper surface of the second die;
a mold compound disposed on the first die, the mold compound encapsulating the second die;
a second conductive pattern disposed on the mold compound, the second conductive pattern electrically connected to the second active circuitry; and
a first via that penetrates the mold compound, an upper end of the first via in contact with the second conductive pattern, a lower end of the first via in contact with the first conductive pattern.

12. The stacked die package of claim 11, further comprising:
a Radio Frequency (RF) shield disposed on a bottom surface of the second die, the RF shield grounded by an electrical connection to the first active circuitry; and
conductive bumps disposed between the second die and the first die, the conductive bumps separating the RF shield from the first active circuitry, the electrical connection including at least one of the conductive bumps.

13. The stacked die package of claim 11, further comprising:
a Radio Frequency (RF) shield disposed on a bottom surface of the second die, the RF shield grounded by an electrical connection to the first active circuitry;
a flexible substrate disposed between the second die and the first die, the flexible substrate separating the RF shield from the first active circuitry; and
a second via that penetrates the flexible substrate, the electrical connection including the second via.

14. The stacked die package of claim 11, further comprising:
a dielectric layer disposed on the mold compound and the second conductive pattern; and
a second via that penetrates the dielectric layer to contact the second conductive pattern.

15. The stacked die package of claim 14, further comprising a third die disposed over the second die, the third die encapsulated by the dielectric layer, a width of the third die less than a width of the first die.

16. A stacked die package comprising:
a first die;
first active circuitry disposed on an upper surface of the first die;
a first conductive pattern disposed on the first active circuitry;
a second die disposed over the first die, the first die wider than the second die in a cross-section of the stacked die package;
second active circuitry disposed on an upper surface of the second die;
a second conductive pattern disposed on the second active circuitry;
a first wirebond that connects the first conductive pattern to the second conductive pattern; and
a mold compound disposed on the first die, the mold compound encapsulating the second die and the wirebond.

17. The stacked die package of claim 16, further comprising:
a third die disposed on the first die and arranged adjacent to the second die;
a third conductive pattern disposed on an upper surface of the third die; and
a second wirebond that connects the first conductive pattern to the third conductive pattern, the mold compound encapsulating the third die and the second wirebond.

18. The stacked die package of claim 16, further comprising:
a third die disposed between the first die and the second die;
third active circuitry disposed on an upper surface of the third die;
a third conductive pattern disposed on the third active circuitry; and
a second wirebond that connects the third conductive pattern to the second conductive pattern, the mold compound encapsulating the third die and the second wirebond.

19. The stacked die package of claim 16, further comprising:
a conductive stud that penetrates the mold compound to contact the second active circuitry;
a dielectric layer disposed on the mold compound and the conductive stud; and
a first via that penetrates the dielectric layer to contact the conductive stud.

20. The stacked die package of claim 16, further comprising an RF shield disposed on a bottom surface of the second die.
